(19) United States
(12) Patent Application Publication
(10) Pub. No.: US 2019/0187553 A1
(43) Pub. Date: Jun. 20, 2019

(54) APPARATUS AND METHODS FOR RETICLE CONFIGURATION

(71) Applicant: SANDISK TECHNOLOGIES LLC, Plano, TX (US)

(72) Inventors: Daniel J. Linnen, Naperville, IL (US); Jianhua Zhu, Saratoga, CA (US); Srikar Peesari, San Jose, CA (US); Kirubakaran Periyannan, Santa Clara, CA (US); Avinash Rajagiri, San Jose, CA (US); Shantanu Gupta, Milpitas, CA (US); Jagdish Sabde, Fremont, CA (US); Ashish Ghai, San Jose, CA (US); Deepak Bharadwaj, Fremont, CA (US)

(73) Assignee: SANDISK TECHNOLOGIES LLC, Plano, TX (US)

(21) Appl. No.: 15/845,456

(22) Filed: Dec. 18, 2017

(51) Int. Cl. G03F 1/50

(52) U.S. Cl. CPC G03F 1/50

(57) ABSTRACT

An apparatus is provided that includes a reticle including a die, the reticle configured to increase a number of partial die that can be successfully used as partially operable die.

### BACKGROUND

Semiconductor devices, such as memories, field programmable gate arrays, central processing units, graphics processing units, application-specific integrated circuits, and other types of integrated circuits, are often manufactured on a semiconductor wafer (or other material). The various layers that constitute an integrated circuit are patterned using a photolithographic process. A reticle includes one or more copies of an image of an integrated circuit die (such as a memory die). For simplicity, an integrated circuit die will be referred to in the remaining discussion as a “die.”

The reticle is used to pattern a layer on a semiconductor wafer, which is typically mounted on a high-precision movable stage. The pattern on the reticle is transferred to the wafer using an optical printing system. The stage is then moved to the next position to be exposed, and this process repeats until the entire wafer is patterned. Each exposure of the reticle is called a “shot,” and the arrangement of shots on the wafer is called a “shot map.” A die typically has a rectangular shape, and the wafer typically is round. As a result, during the patterning process, some of die will have a portion of the die off the wafer edge. Such incomplete die are typically referred to as a partial die.

For example, FIG. 1A depicts a reticle 100 that includes four die 102, and includes a first reticle portion 100a and a second reticle portion 100b which is identical to first reticle portion 100a. FIG. 1B depicts a shot map 104 based on reticle 100 superimposed on a wafer 106. Each die 102 includes a first die region 108 and a second die region 110, and shot map 104 includes seven shots of reticle 100. The characters “a” and “b” shown in first die region 108 and second die region 110, respectively, are used as simplified representation of circuit elements that included throughout each region. Shot map 104 includes twenty-eight die 102, including four partial die 102a, 102b, 102c and 102d (shown shaded). As illustrated in FIG. 1B, a portion of first die region 108 is cut off in partial die 102a and 102b, and a portion of second die region 110 is cut off in partial die 102c and 102d.

In the past, partial memory die such as partial die 102a, 102b, 102c and 102d of FIG. 1B were discarded because they were missing components and, therefore, did not properly function.

### BRIEF DESCRIPTION OF THE DRAWINGS

Like-numbered elements refer to common components in the different figures.

FIG. 1A depicts an embodiment of a reticle.

FIG. 1B depicts an embodiment of a shot map based on the reticle of FIG. 1A.

FIG. 2 is a block diagram of an embodiment of a memory system.

FIG. 3 is another block diagram of an embodiment of a memory system.

FIG. 4 is a block diagram of an embodiment of a memory array.

FIG. 5A depicts an embodiment of a complete memory die.

FIGS. 5B-5C depicts embodiments of partial memory die.

FIG. 6 depicts an embodiment of multiple die printed on a wafer using the reticle of FIG. 1A.

FIG. 7A depicts an embodiment of a reticle.

FIG. 7B depicts an embodiment of a shot map based on the reticle of FIG. 7A.

FIG. 7C depicts an embodiment of multiple die printed on a wafer using the reticle of FIG. 7A.

FIG. 8A depicts another embodiment of a reticle.

FIG. 8B depicts an embodiment of a shot map based on the reticle of FIG. 8A.

FIG. 8C depicts an embodiment of multiple die printed on a wafer using the reticle of FIG. 8A.

FIG. 9A depicts still another embodiment of a reticle.

FIG. 9B depicts an embodiment of a shot map based on the reticle of FIG. 9A.

FIG. 9C depicts an embodiment of multiple die printed on a wafer using the reticle of FIG. 9A.

### DETAILED DESCRIPTION

Technology is described for increasing a number of partial die that can be successfully used as partially operable die. In particular, a reticle is provided that is configured to increase a number of partial die that can be successfully used as partially operable die.

In an embodiment, the reticle includes a first reticle portion and a second reticle portion. In an embodiment, each reticle portion includes a die that includes a first die region and a second die region. In an embodiment, a first type of partial die includes a partial first die region and a complete second die region, and a second type of partial die includes a complete first die region and a partial second die region. In an embodiment, the first type of partial die can be successfully used as a partially operable die, and the second type of partial die cannot be successfully used as a partially operable die.

In an embodiment, the first reticle portion and the second reticle portion are configured to increase a number of the first type of partial die and decrease a number of the second type of partial die. In an embodiment, the second reticle portion is a mirrored image of the first reticle portion. In another embodiment, the second reticle portion is a mirrored and inverted image of the first reticle portion. In yet another embodiment, the second reticle portion is a same image of the first reticle portion.

In an embodiment, the first die region includes multiple arrays of circuits and/or duplicate circuits, and second die region includes circuits connected to circuits in the first die region. In embodiments, each die includes one or more of a memory device, a field programmable gate array (FPGA), a central processing unit (CPU), a graphics processing unit (GPU), an application-specific integrated circuit (ASIC), or other type of integrated circuit that includes multiple arrays of circuits and/or duplicate circuits. For simplicity, the remaining discussion will describe the technology for die that include memory circuits. Persons of ordinary skill in the art will understand that the described technology also may be used with other type of circuit, such as described above.

In an embodiment, the first die region includes portions of a substrate, and memory blocks that include memory cells, NAND strings, bit lines, word lines, select lines and dielectric regions, and the second die region comprises support circuits connected to circuits in the first die region.

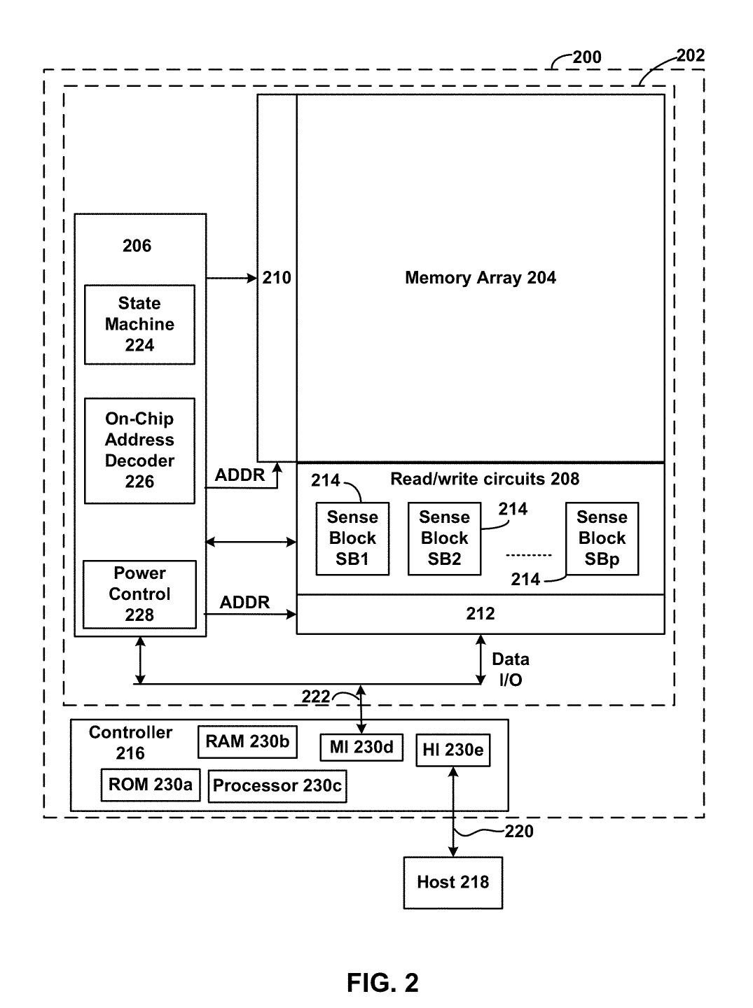

FIG. 2 is a functional block diagram of an example memory system that can be implemented on a partial die and successfully programmed and read. The components depicted in FIG. 2 are electrical circuits. Memory system 200 includes one or more memory die 202. Each memory die 202 includes a three dimensional (“3D”) memory array 204 of memory cells (such as, for example, a three dimensional monolithic array of memory cells), control circuitry 206, and read/write circuits 208. In other embodiments, a two dimensional array of memory cells can be used.

Memory array 204 is addressable by word lines via a row decoder 210 and by bit lines via a column decoder 212. Read/write circuits 208 include multiple sense blocks 214 including SB1, SB2, . . . , SBp (sensing circuitry) and allow a page of memory cells to be read or programmed in parallel.

In some memory systems, a controller 216 is included in the same memory device 200 (e.g., a removable storage card) as the one or more memory die 202. However, in other systems, controller 216 can be separated from memory die 202. In some embodiments controller 216 will be on a different die than memory die 202. In some embodiments, one controller 216 will communicate with multiple memory die 202. In other embodiments, each memory die 202 has its own controller. Commands and data are transferred between a host 218 and controller 216 via a data bus 220, and between controller 216 and the one or more memory die 202 via lines 222. In one embodiment, memory die 202 includes a set of input and/or output (I/O) pins that connect to lines 222.

Memory array 204 may include one or more arrays of non-volatile memory cells including a 3D array. Memory array 204 may include a monolithic three dimensional memory structure in which multiple memory levels are formed above (and not in) a single substrate, such as a wafer, with no intervening substrates. Memory array 204 may include any type of non-volatile memory that is monolithically formed in one or more physical levels of arrays of memory cells having an active area disposed above a silicon substrate. Memory array 204 may be in a non-volatile memory device having circuitry associated with the operation of the memory cells, whether the associated circuitry is above or within the substrate.

Control circuitry 206 cooperates with the read/write circuits 208 to perform memory operations (e.g., erase, program, read, and others) on memory array 204, and includes a state machine 224, an on-chip address decoder 226, and a power control module 228. State machine 224 provides die-level control of memory operations. In one embodiment, state machine 224 is programmable by software. In other embodiments, state machine 224 does not use software and is completely implemented in hardware (e.g., electrical circuits). In one embodiment, control circuitry 206 includes registers, ROM fuses and other storage devices for storing default values such as base voltages and other parameters.

On-chip address decoder 226 provides an address interface between addresses used by host 218 or controller 216 to the hardware address used by row decoder 210 and column decoder 212. Power control module 228 controls the power and voltages supplied to the word lines and bit lines during memory operations. Power control module 228 may include charge pumps for creating voltages. Sense blocks 214 include bit line drivers.

State machine 224 and/or controller 216, including various combinations of one or more of row decoder 210, column decoder 212, on-chip address decoder 226, power control module 228, sense blocks 214, and read/write circuits 208, can be considered one or more control circuits (or a managing circuit) that performs the functions described herein. The one or more control circuits can include hardware only or a combination of hardware and software (including firmware). For example, a controller programmed by firmware to perform the functions described herein is one example of a control circuit.

The (on-chip or off-chip) controller 216 (which in one embodiment is an electrical circuit) may include one or more ROM 230a, RAM 230b, processors 230c, a memory interface 230d and a host interface 230e, all of which are interconnected. One or more processors 230c are one example of a control circuit. Other embodiments can use state machines or other custom circuits designed to perform one or more functions.

The storage devices (ROM 230a, RAM 230b) stored code (software) such as a set of instructions (including firmware), and one or more processors 230c are operable to execute the set of instructions to provide the functionality described herein. Alternatively or additionally, one or more processors 230c can access code from a storage device in memory array 204, such as a reserved area of memory cells connected to one or more word lines.

RAM 230b can be used to store data for controller 216, including caching program data. Memory interface 230d, in communication with ROM 230a, RAM 230b and processor 230c, is an electrical circuit that provides an electrical interface between controller 216 and one or more memory die 202. For example, memory interface 230d can change the format or timing of signals, provide a buffer, isolate from surges, latch I/O, etc.

One or more processors 230c can issue commands to control circuitry 206 (or any other component of memory die 202) via memory interface 230d. In one embodiment, one or more processors 230c can access code from ROM 230a or RAM 230b to receive a request to read from host 218 that includes an operation limitation, perform a read process on the memory die 202 within the operation limitation and return data to host 218 from the read process that includes errors in response to the request to read. Host interface 230e provides an electrical interface with data bus 220 to receive commands, addresses and/or data from host 218 to provide data and/or status to host 218.

In one example memory system 200, memory array 204 includes a three dimensional memory structure that includes flash memory vertical NAND strings with charge-trapping material. However, other (2D and 3D) memory structures also can be used with the technology described herein. For example, floating gate memories (e.g., NAND-type and NOR-type flash memory), ReRAM cross-point memories, magnetoresistive memory (e.g., MRAM), and phase change memory (e.g., PCRAM) can also be used.

One example of a ReRAM cross point memory includes reversible resistance-switching elements arranged in cross point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Magnetoresistive memory (MRAM) stores data by magnetic storage elements. The elements are formed from two ferromagnetic plates, each of which can hold a magnetization, separated by a thin insulating layer. One of the two plates is a permanent magnet set to a particular polarity; the other plate's magnetization can be changed to match that of an external field to store memory. This configuration is known as a spin valve and is the simplest structure for an MRAM bit. A memory device is built from a grid of such memory cells. In one embodiment for programming, each memory cell lies between a pair of write lines arranged at right angles to each other, parallel to the cell, one above and one below the cell. When current is passed through them, an induced magnetic field is created.

Phase change memory (PCRAM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. Note that the use of “pulse” in this document does not require a square pulse, but includes a (continuous or non-continuous) vibration or burst of sound, current, voltage light, or other wave.

A person of ordinary skill in the art will recognize that the technology described herein is not limited to a single specific memory structure, but covers many relevant memory structures within the spirit and scope of the technology as described herein and as understood by one of ordinary skill in the art.

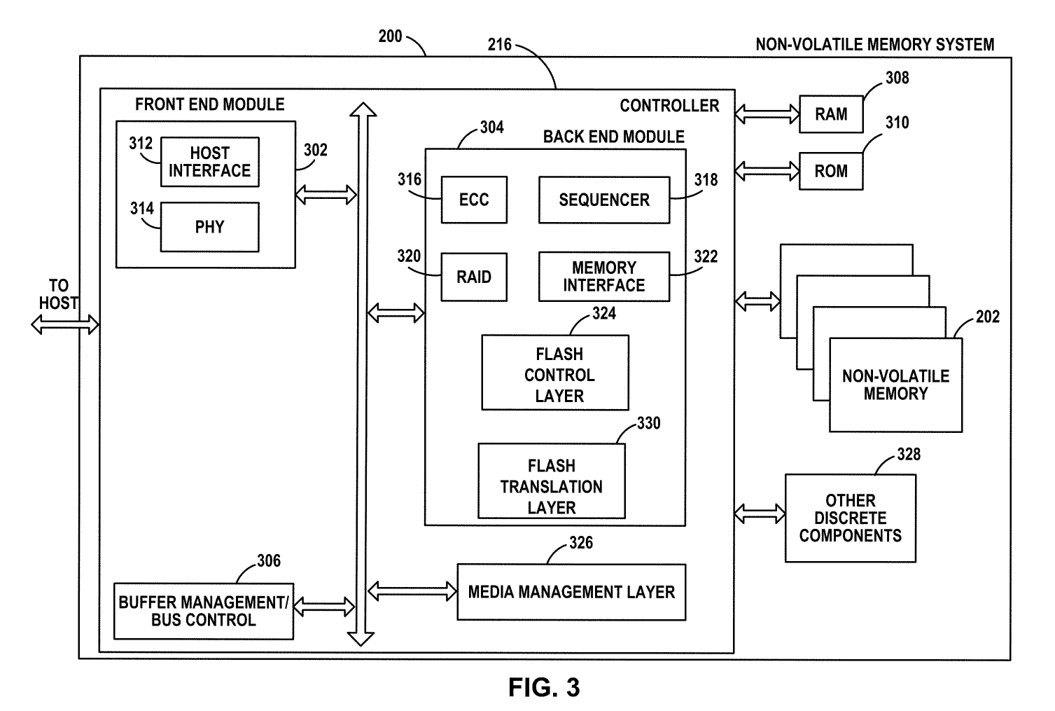

FIG. 3 is another block diagram of example memory system 200, depicting more details of one example implementation of controller 216. As used herein, a flash memory controller is a device that manages data stored on flash memory and communicates with a host, such as a computer or electronic device.

A flash memory controller can have various functionality in addition to the specific functionality described herein. For example, the flash memory controller can manage the read and programming processes, format the flash memory to ensure the memory is operating properly, map out bad flash memory cells, and allocate spare memory cells to be substituted for future failed cells. Some part of the spare memory cells can be used to hold firmware to operate the flash memory controller and implement other features.

In operation, when a host needs to read data from or write data to the flash memory, the host will communicate with the flash memory controller. If the host provides a logical address to which data is to be read/written, the flash memory controller can convert the logical address received from the host to a physical address in the flash memory. (Alternatively, the host can provide the physical address).

The flash memory controller also can perform various memory management functions, such as, but not limited to, wear leveling (distributing writes to avoid wearing out specific blocks of memory that would otherwise be repeatedly written to) and garbage collection (after a block is full, moving only the valid pages of data to a new block, so the full block can be erased and reused).

The interface between controller 216 and non-volatile memory die 202 may be any suitable memory interface, such as Toggle Mode 200, 400, or 800. In one embodiment, memory system 200 may be a card based system, such as a secure digital (SD) or a micro secure digital (micro-SD) card that can be in or connected to cellular telephones, computers, servers, smart appliances, digital cameras, etc. In an alternate embodiment, memory system 200 may be part of an embedded memory system. In another example, memory system 200 may be in the form of a solid state disk (SSD) drive (having one or, more memory die 202) installed in or connected to a personal computer or server. Examples of hosts are cellular telephones, computers, servers, smart appliances, digital cameras, etc.

In some embodiments, non-volatile memory system 200 includes a single channel between controller 216 and non-volatile memory die 202, however, the subject matter described herein is not limited to having a single memory channel. For example, in some memory system architectures, 2, 4, 8 or more channels may exist between the controller and a memory die, depending on controller capabilities. In any of the embodiments described herein, more than a single channel may exist between the controller and the memory die, even if a single channel is shown in the drawings.

As depicted in FIG. 3, controller 216 includes a front end module 302 that interfaces with a host, a back end module 304 that interfaces with the one or more non-volatile memory die 202, and various other modules that perform functions which will now be described in detail.

The components of controller 216 depicted in FIG. 3 may take the form of a packaged functional hardware unit (e.g., an electrical circuit) designed for use with other components, a portion of a program code (e.g., software or firmware) executable by a (micro) processor or processing circuitry that usually performs a particular function or related functions, or a self-contained hardware or software component that interfaces with a larger system, for example.

For example, each module may include an application specific integrated circuit (ASIC), a Field Programmable Gate Array (FPGA), a circuit, a digital logic circuit, an analog circuit, a combination of discrete circuits, gates, or any other type of hardware or combination thereof Alternatively or in addition, each module may include software stored in a processor readable device (e.g., memory) to program a processor or circuit for controller 216 to perform the functions described herein. The architecture depicted in FIG. 3 is one example implementation that may (or may not) use the components of controller 216 depicted in FIG. 2 (i.e., RAM, ROM, processor, interface).

Referring again to modules of controller 216, a buffer manager/bus control 306 manages buffers in random access memory (RAM) 308 and controls the internal bus arbitration of controller 216. A read only memory (ROM) 310 stores system boot code. Although illustrated in FIG. 3 as located separately from the controller 216, in other embodiments one or both of the RAM 308 and ROM 310 may be located within controller 216. In yet other embodiments, portions of RAM 308 and ROM 310 may be located both within and without controller 216. Further, in some implementations, controller 216, RAM 308, and ROM 310 may be located on separate semiconductor die. In some embodiments, a portion of RAM 308 is used to cache program data.

Front end module 302 includes a host interface 312 and a physical layer interface (PHY) 314 that provide the electrical interface with the host or next level storage controller. The choice of the type of host interface 312 can depend on the type of memory being used. Examples of host interfaces 312 include, but are not limited to, SATA, SATA Express, SAS, Fibre Channel, USB, PCIe, and NVMe. Host interface 312 typically facilitates transfer for data, control signals, and timing signals.

Back end module 304 includes an error correction code (ECC) engine 316 (electrical circuit, software or combination of circuit and software) that encodes the data bytes received from the host, and decodes and error corrects the data bytes read from the non-volatile memory. A command sequencer 318 generates command sequences, such as program/read/erase command sequences, to be transmitted to non-volatile memory die 202. A RAID (Redundant Array of Independent Dies) module 320 manages generation of RAID parity and recovery of failed data.

The RAID parity may be used as an additional level of integrity protection for the data being written into the non-volatile memory system 200. In some cases, RAID module 320 may be a part of ECC engine 316. Note that the RAID parity may be added as one or more extra die as implied by the common name, but it may also be added within the existing die, e.g. as an extra plane, or extra block, or extra word lines within a block.

A memory interface 322 provides the command sequences to non-volatile memory die 202 and receives status information from non-volatile memory die 202. In one embodiment, memory interface 322 may be a double data rate (DDR) interface, such as a Toggle Mode 200, 400, or 800 interface.

A flash control layer 324 (firmware and/or hardware, such as an electrical circuit) controls the overall operation of back end module 304. Flash control layer 324 includes a program manager that manages the programming processes described below. The program manager can be implemented as a dedicated electrical circuit or via software (e.g., firmware).

Additional components of memory system 200 illustrated in FIG. 3 include media management layer 326, which performs wear leveling of memory cells of non-volatile memory die 202. Memory system 200 also includes other discrete components 328, such as external electrical interfaces, external RAM, resistors, capacitors, or other components that may interface with controller 216.

In alternative embodiments, one or more of physical layer interface 314, RAID module 320, media management layer 326 and buffer management/bus controller 306 are optional components that are not necessary in controller 216.

Flash translation layer 330 manages the translation between logical addresses and physical addresses. Logical addresses are used to communicate with the host. Physical addresses are used to communicate with the memory die. Flash translation layer 330 can be a dedicated electrical circuit or firmware.

Controller 216 may interface with one or more memory die 202. In one embodiment, controller 216 and multiple memory die 202 (together comprising memory system 200) implement a SSD, which can emulate, replace or be used instead of a hard disk drive inside or connected to a host, as a NAS device, etc. Additionally, the SSD need not be made to emulate a hard drive.

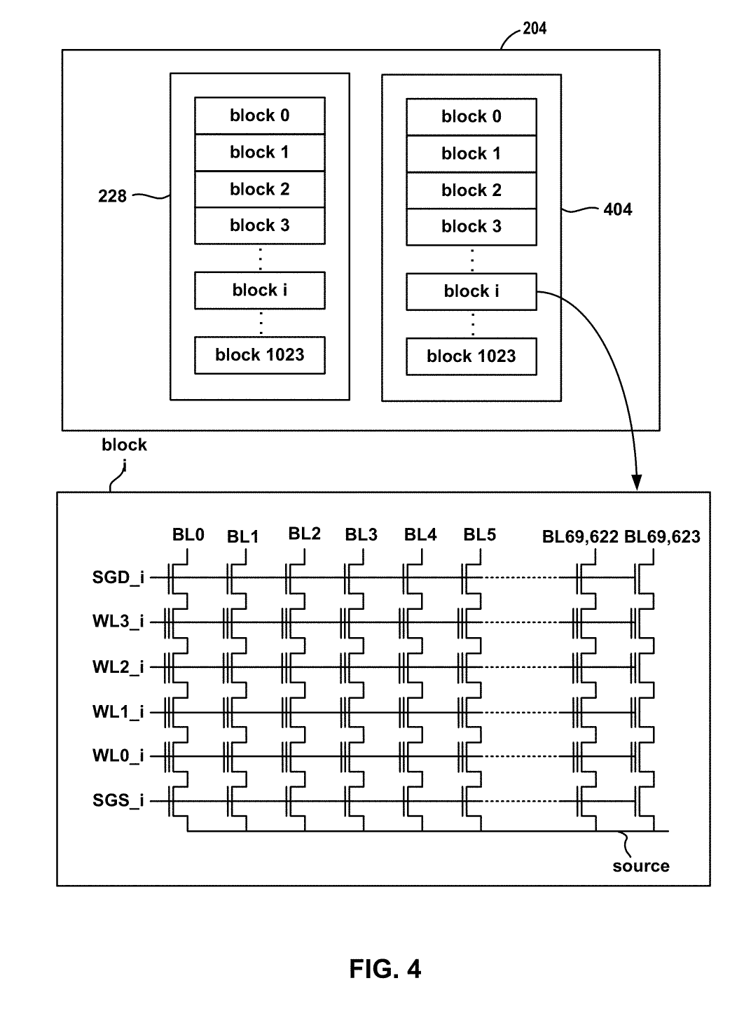

FIG. 4 depicts an exemplary structure of memory array 204. In one embodiment, the array of memory cells is divided into multiple planes. In the example of FIG. 4, memory array 204 is divided into two planes: Plane 402 and Plane 404. In other embodiments, more or fewer than two planes can be used.

In some embodiments, each plane is divided into a large number of blocks (e.g., blocks 0-1023, or another amount). Each block includes many memory cells. In one embodiment, the block is the unit of erase. That is, each block contains the minimum number of memory cells that are erased together. Other units of erase also can be used.

In one embodiment, a block contains a set of NAND strings which are accessed via bit lines (e.g., bit lines BL0-BL69,623) and word lines (WL0, WL1, WL2, WL3). FIG. 4 shows four memory cells connected in series to form a NAND string. Although four cells are depicted in each NAND string, more or less than four memory cells can be used (e.g., 16, 32, 64, 220, 256 or another number or memory cells can be on a NAND string).

One terminal of the NAND string is connected to a corresponding bit line via a drain select gate (connected to select gate drain line SGD), and another terminal is connected to a source line via a source select gate (connected to select gate source line SGS). Although FIG. 4 shows 69624 bit lines, a different number of bit lines also can be used. Additionally, as discussed above, the block can implement non-volatile storage technologies other than NAND flash memory.

Each block is typically divided into a number of pages. In one embodiment, a page is a unit of programming. Other units of programming also can be used. One or more pages of data are typically stored in one row of memory cells. For example, one or more pages of data may be stored in memory cells connected to a common word line. A page includes user data and overhead data (also called system data). Overhead data typically includes header information and Error Correction Codes (ECC) that have been calculated from the user data of the sector. The controller (or other component) calculates the ECC when data is being programmed into the array, and also checks it when data is being read from the array.

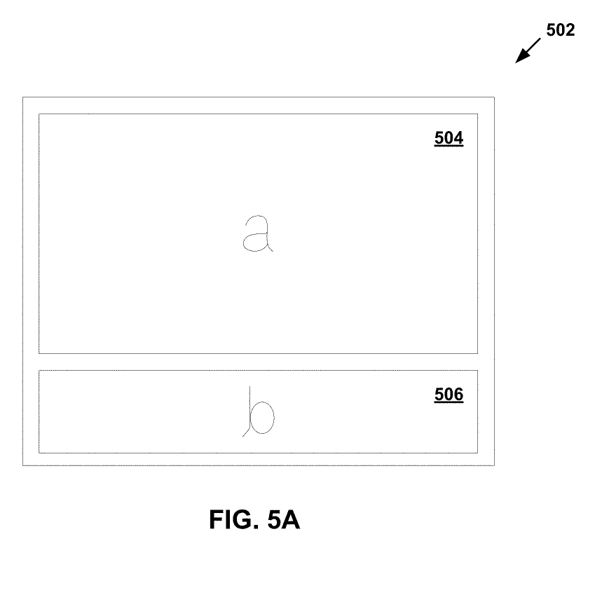

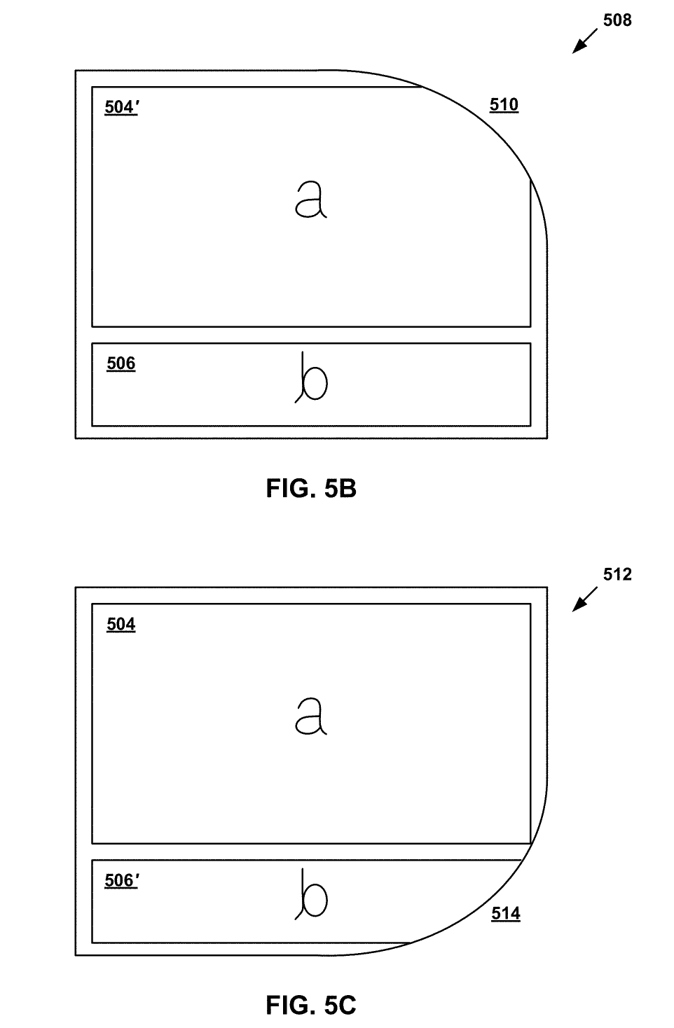

FIG. 5A shows a complete memory die 502 that includes a first die region 504 and a second die region 506. The characters “a” and “b” shown in first die region 504 and second die region 506, respectively, are a simplified representation of an alignment of features in each region. In an embodiment, first die region 504 includes portions of the substrate, and memory blocks that include memory cells, NAND strings, bit lines, word lines, select lines and dielectric regions. In an embodiment, second die region 506 includes support circuits connected to the circuits in first die region 504. Support circuits can include one or more circuits that may be referred to as a control circuits for successfully erasing, programming and reading memory blocks. In an embodiment, the support circuits in second die region 506 include control circuits 206, read/write circuits 208, row decoder 210, and column decoder 212 of FIG. 2. Other circuits also can be included in second die region 506.

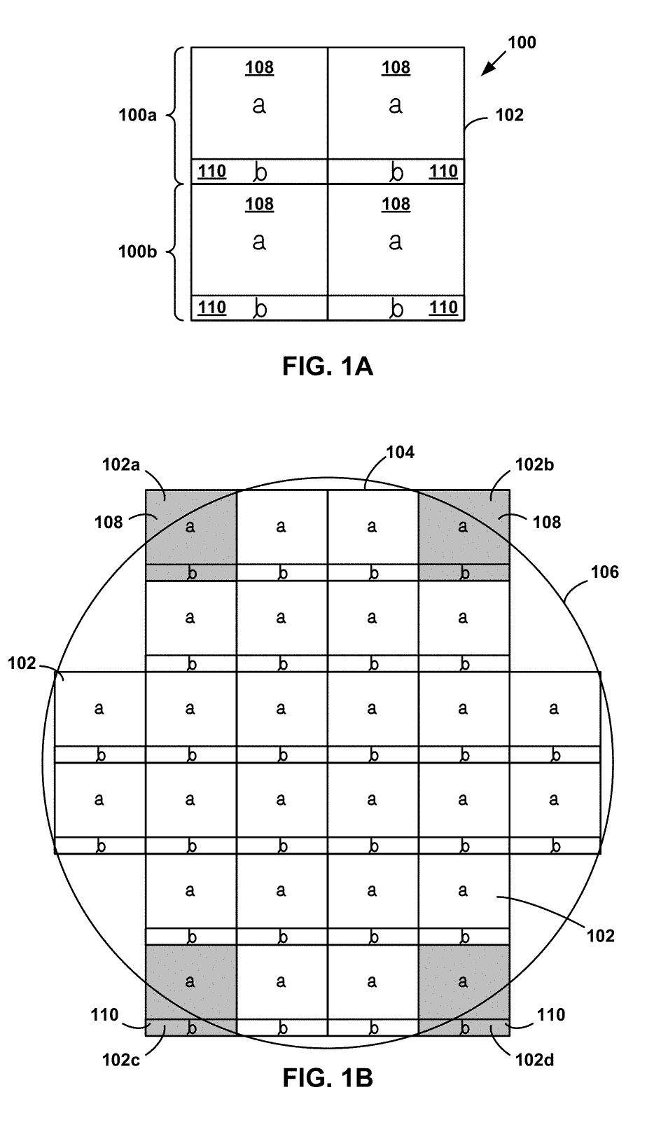

FIG. 5B shows a first partial memory die 508, which includes an incomplete memory structure/array. For example, first partial memory die 508 was removed from an edge of a wafer. First partial memory die 508 includes a partial first die region 504′ and a complete second die region 506 of FIG. 5A, and is missing a portion 510 of first die region 504 of FIG. 5A that was not printed (or otherwise fabricated) on the wafer. That is, missing portion 510 should be part of first partial memory die 508 but was not printed on the wafer because first partial memory die 508 was at the edge of the wafer, such as described above regarding partial die 102b of FIG. 1B.

Missing portion 510 can include portions of the substrate, portions of memory blocks that include memory cells, portions or entire NAND strings, portions or entire bit lines, portions or entire word lines, portions or entire select lines and dielectric regions. In some embodiments, partial first die region 504′ includes multiple blocks. Some of the blocks in partial first die region 504′ are complete blocks, meaning that they are not missing any components.

Some of the blocks in partial first die region 504′ are incomplete blocks, meaning that they are missing components. The blocks missing components are physically partial memory blocks because they are missing silicon components corresponding to silicon components found in complete memory blocks. For example, the physically partial memory blocks (incomplete blocks) are missing non-volatile memory cells, bit lines, portions of bit lines, word lines, portions of word line and portions of substrate corresponding to respective memory cells, bit lines, portions of bit lines, word lines, portions of word line and portions of substrate found in complete memory blocks.

First partial memory die 508 includes a complete second die region 506 of FIG. 5A, which includes support circuits connected to the circuits in partial first die region 504′. In an embodiment, the support circuits in second die region 506 include one or more control circuits that may be used to successfully erase, program and read some portion of memory blocks in partial first die region 504′. In an embodiment, second die region 506 includes control circuits 206, read/write circuits 208, row decoder 210, and column decoder 212 of FIG. 2. In an embodiment, first partial memory die 508 need not be discarded, and can be successfully used as a partially operable memory die.

FIG. 5C shows a second partial memory die 512, which includes an incomplete memory structure/array. For example, second partial memory die 512 was removed from an edge of a wafer. Second partial memory die 512 includes a complete first die region 504 of FIG. 5A and a partial second die region 506′, and is missing a portion 514 of second die region 506 of FIG. 5A that was not printed (or otherwise fabricated) on the wafer. That is, missing portion 514 should be part of second partial memory die 512 but was not printed on the wafer because second partial memory die 512 was at the edge of the wafer, such as described above regarding partial die 102d of FIG. 1B.

In an embodiment, partial second die region 506′ and missing portion 514 each include portions of support circuits connected to the circuits in first die region 504. In an embodiment, partial second die region 506′ and missing portion 514 each include portions of one or more control circuits for successfully erasing, programming and reading memory blocks. In an embodiment, partial second die region 506′ and missing portion 514 include portions of control circuits 206, read/write circuits 208, row decoder 210, and column decoder 212 of FIG. 2.

First die region 504 in second partial memory die 512 includes portions of the substrate, and complete memory blocks that include memory cells, NAND strings, bit lines, word lines, select lines and dielectric regions. In an embodiment, the portions of support circuits in partial second die region 506′ cannot be used to successfully erase, program and read complete memory blocks in first die region 504. That is, without the portions of support circuits in missing portion 514, partial second die region 506′ cannot be used to successfully erase, program and read complete memory blocks in first die region 504. Thus, in contrast to first partial memory die 508 of FIG. 5B, second partial memory die 512 cannot be successfully used as a partially operable memory die.

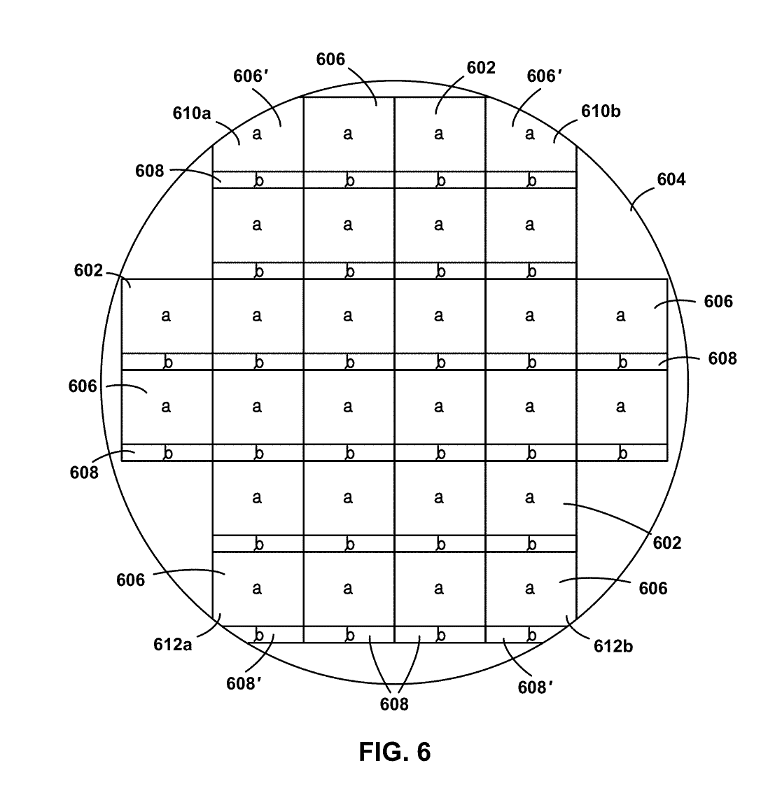

FIG. 6 depicts multiple die 602 printed using a reticle (e.g., reticle 100 of FIG. 1A) on a wafer 604. Each die 602 includes a first die region 606 and a second die region 608. Wafer 604 also includes first partial memory die 610a and 610b, and second partial memory die 612a and 612b.

First partial memory die 610a and 610b each include a partial first die region 606′ and a complete second die region 608, and are each missing portions of first die region 606 that were not printed (or otherwise fabricated) on wafer 604. In an embodiment, first partial memory die 610a and 610b each can be successfully used as a partially operable memory die.

Second partial memory die 612a and 612b each include a complete first die region 606 and a partial second die region 608′, and are each missing portions of second die region 608 that were not printed (or otherwise fabricated) on wafer 604. In an embodiment, second partial memory die 612a and 612b cannot be successfully used as a partially operable memory die. As such, second partial memory die 608a and 608b typically are discarded.

Technology is described for increasing a number first partial die (such as first partial memory die 610a and 610b of FIG. 6) that can be successfully used as a partially operable die, and for reducing or eliminating a number of second partial die (such as second partial memory die 612a and 612b of FIG. 6) that cannot be successfully used as a partially operable die from fabricated wafers.

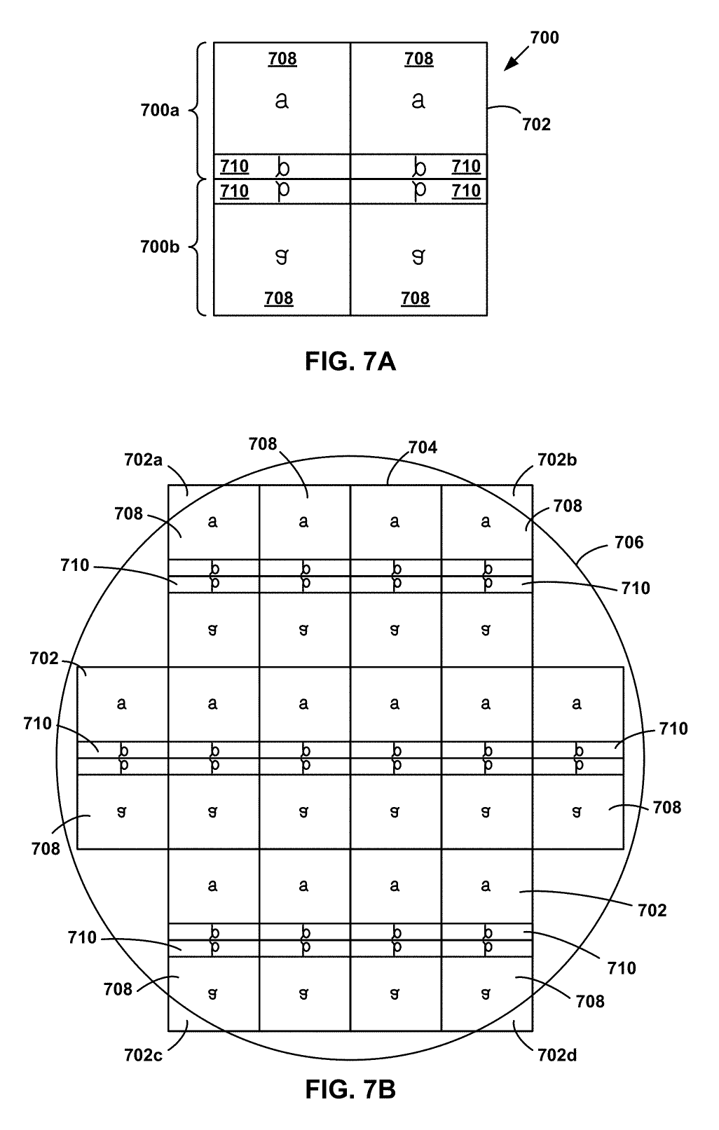

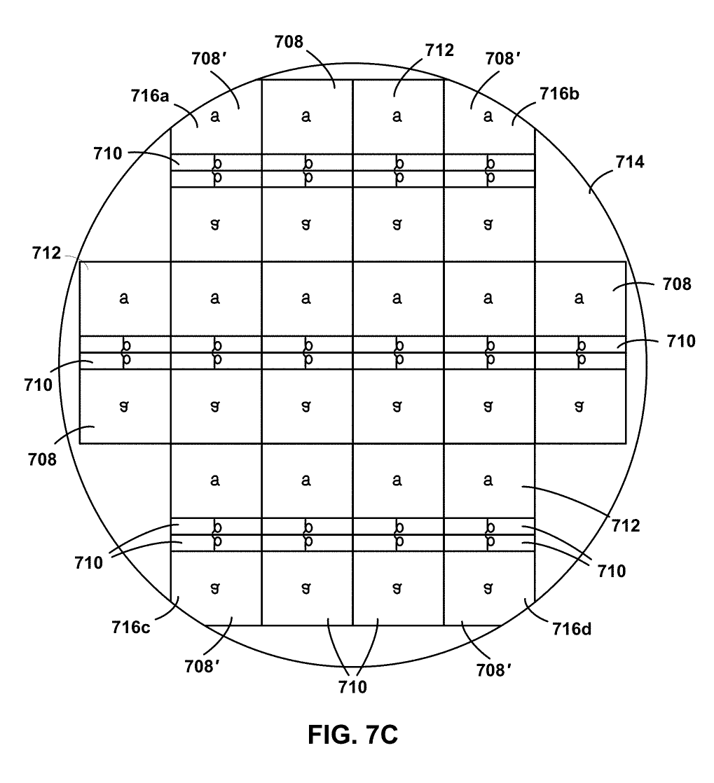

FIG. 7A depicts an embodiment of a reticle 700 that includes four die 702, and includes a first reticle portion 700a and a second reticle portion 700b which is a vertically mirrored image of first reticle portion 700a. In other embodiments, reticle 700 may include more or fewer than four die 702, and may include more than two portions.

Each die 702 includes a first die region 708 and a second die region 710. The characters “a” and “b” shown in first die region 708 and second die region 710, respectively, are a simplified representation of an alignment of features in each region. In an embodiment, first die region 708 includes portions of the substrate, and memory blocks that include memory cells, NAND strings, bit lines, word lines, select lines and dielectric regions. In an embodiment, second die region 710 includes support circuits connected to the circuits in first die region 708. Support circuits can include one or more circuits that may be referred to as a control circuits for successfully erasing, programming and reading memory blocks. In an embodiment, the support circuits in second die region 710 include control circuits 206, read/write circuits 208, row decoder 210, and column decoder 212 of FIG. 2. Other circuits also can be included in second die region 710. In other embodiments, each die 702 may include more than two regions.

FIG. 7B depicts a shot map 704 based on reticle 700 superimposed on a wafer 706. Shot map 704 includes seven shots of reticle 700. In other embodiments, shot map 704 may include more or fewer than seven shots of reticle 700. Shot map 704 includes twenty-eight die 702, including four partial die 702a, 702b, 702c and 702d. In an embodiment, a portion of first die region 708 is cut off in each of partial die 702a, 702b, 702c and 702d. In an embodiment, no portion of second die region 710 is cut off in any of partial die 702a, 702b, 702c and 702d.

FIG. 7C depicts multiple die 712 printed using reticle 700 of FIG. 7A on a wafer 714. Each die 712 includes first die region 708 and second die region 710. Wafer 714 also includes first partial memory die 716a, 716b, 716c and 716d.

First partial memory die 716a, 716b, 716c and 716d each include a partial first die region 708′ and a second die region 710, and are each missing portions of first die region 708 that were not printed (or otherwise fabricated) on wafer 714. In an embodiment, first partial memory die 716a, 716b, 716c and 716d each can be successfully used as a partially operable memory die. Wafer 714 includes no second partial memory die that include partial second die region 710. Thus, compared with wafer 604 of FIG. 6, wafer 714 includes two additional first partial memory die that can be successfully used as a partially operable memory die, and includes no second partial memory die that cannot be successfully used as a partially operable memory die.

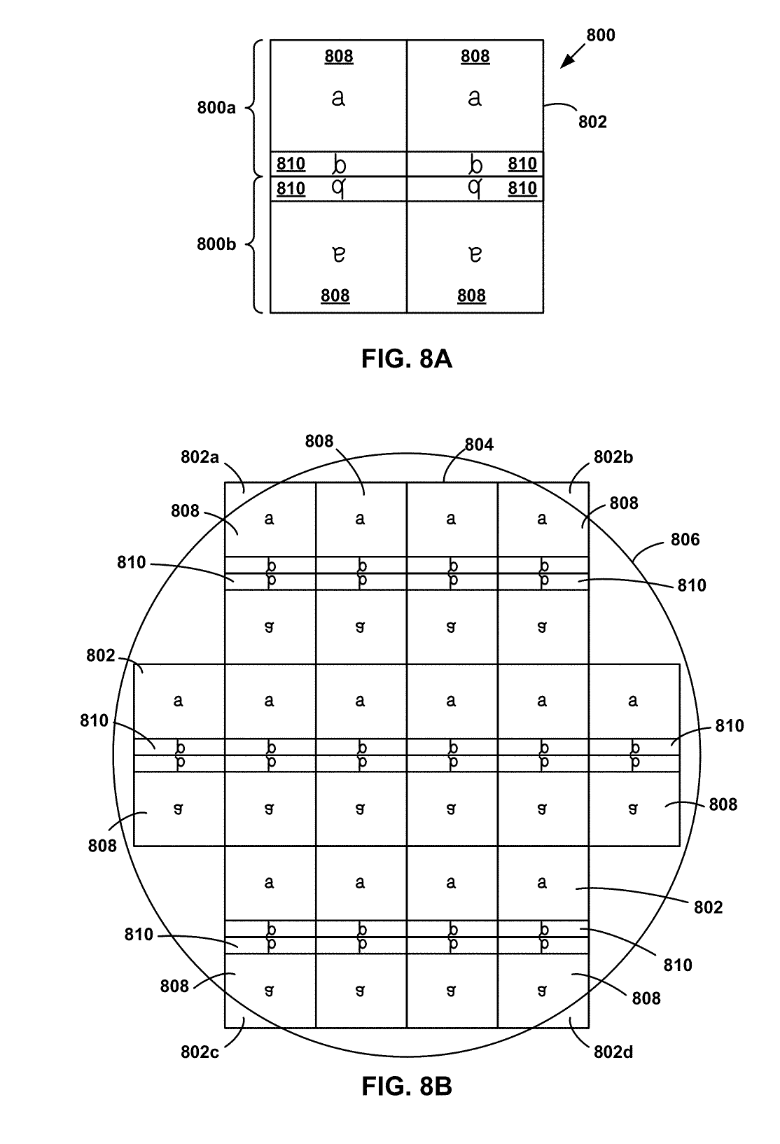

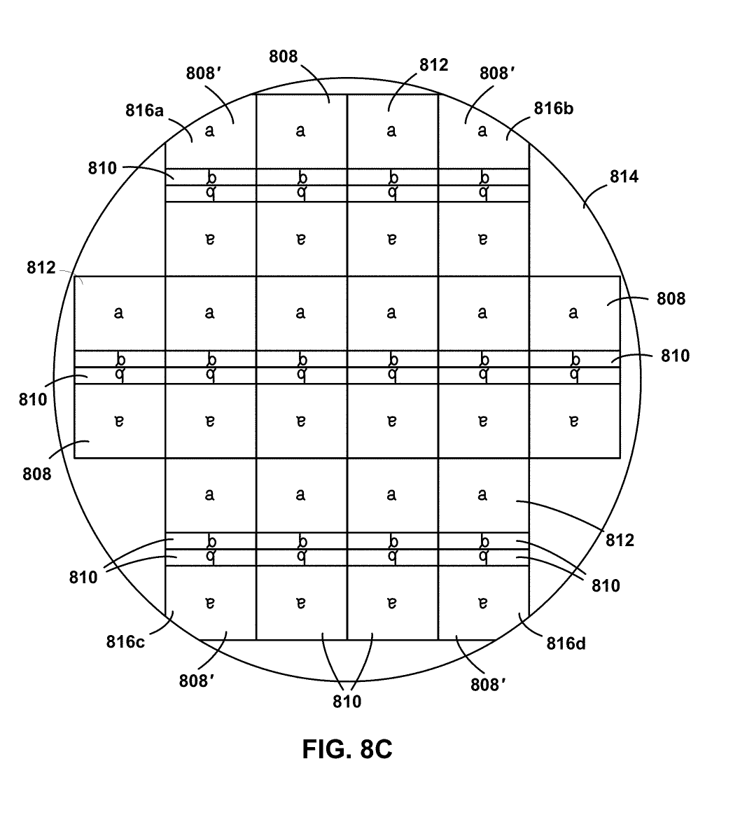

FIG. 8A depicts an embodiment of a reticle 800 that includes four die 802, and includes a first reticle portion 800a and a second reticle portion 800b which is a vertically and horizontally mirrored image of first reticle portion 800a. In other embodiments, reticle 800 may include more or fewer than four die 802, and may include more than two portions.

Each die 802 includes a first die region 808 and a second die region 810. The characters “a” and “b” shown in first die region 808 and second die region 810, respectively, are a simplified representation of an alignment of features in each region. In an embodiment, first die region 808 includes portions of the substrate, and memory blocks that include memory cells, NAND strings, bit lines, word lines, select lines and dielectric regions. In an embodiment, second die region 810 includes support circuits connected to the circuits in first die region 808. Support circuits can include one or more circuits that may be referred to as a control circuits for successfully erasing, programming and reading memory blocks. In an embodiment, the support circuits in second die region 810 include control circuits 206, read/write circuits 208, row decoder 210, and column decoder 212 of FIG. 2. Other circuits also can be included in second die region 810. In other embodiments, each die 802 may include more than two regions.

FIG. 8B depicts a shot map 804 based on reticle 800 superimposed on a wafer 806. Shot map 804 includes seven shots of reticle 800. In other embodiments, shot map 804 may include more or fewer than seven shots of reticle 800. Shot map 804 includes twenty-eight die 802, including four partial die 802a, 802b, 802c and 802d. In an embodiment, a portion of first die region 808 is cut off in each of partial die 802a, 802b, 802c and 802d. In an embodiment, no portion of second die region 810 is cut off in any of partial die 802a, 802b, 802c and 802d.

FIG. 8C depicts multiple die 812 printed using reticle 800 of FIG. 8A on a wafer 814. Each die 812 includes first die region 808 and second die region 810. Wafer 814 also includes first partial memory die 816a, 816b, 816c and 816d.

First partial memory die 816a, 816b, 816c and 816d each include a partial first die region 808′ and a second die region 810, and are each missing portions of first die region 808 that were not printed (or otherwise fabricated) on wafer 814. In an embodiment, first partial memory die 816a, 816b, 816c and 816d each can be successfully used as a partially operable memory die. Wafer 814 includes no second partial memory die that include partial second die region 810. Thus, compared with wafer 604 of FIG. 6, wafer 814 includes two additional first partial memory die that can be successfully used as a partially operable memory die, and includes no second partial memory die that cannot be successfully used as a partially operable memory die.

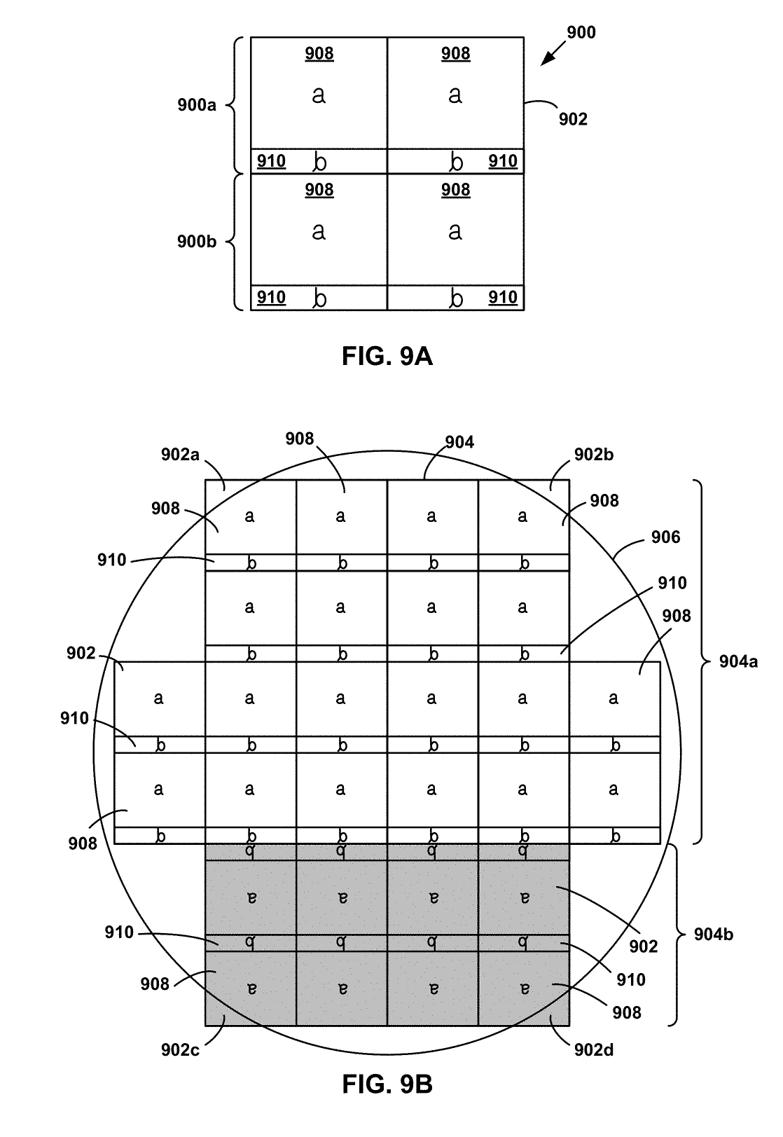

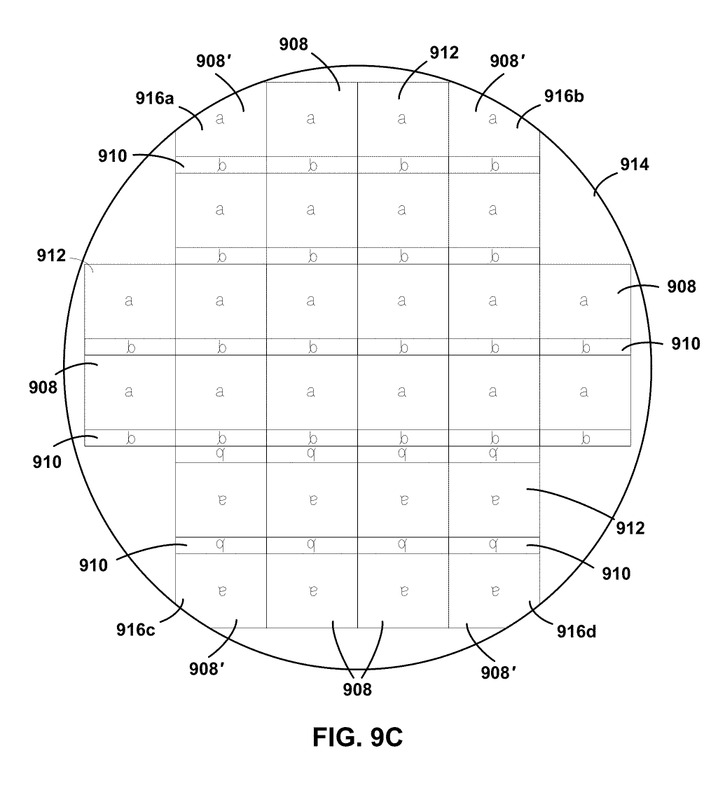

FIG. 9A depicts an embodiment of a reticle 900 that includes four die 902, and includes a first reticle portion 900a and a second reticle portion 900b which is a same image as first reticle portion 900a. In other embodiments, reticle 900 may include more or fewer than four die 902, and may include more than two portions.

Each die 902 includes a first die region 908 and a second die region 910. The characters “a” and “b” shown in first die region 908 and second die region 910, respectively, are a simplified representation of an alignment of features in each region. In an embodiment, first die region 908 includes portions of the substrate, and memory blocks that include memory cells, NAND strings, bit lines, word lines, select lines and dielectric regions. In an embodiment, second die region 910 includes support circuits connected to the circuits in first die region 908. Support circuits can include one or more circuits that may be referred to as a control circuits for successfully erasing, programming and reading memory blocks. In an embodiment, the support circuits in second die region 910 include control circuits 206, read/write circuits 208, row decoder 210, and column decoder 212 of FIG. 2. Other circuits also can be included in second die region 910. In other embodiments, each die 902 may include more than two regions.

FIG. 9B depicts a shot map 904 based on reticle 900 superimposed on a wafer 906. Shot map 904 includes seven shots of reticle 900. In other embodiments, shot map 904 may include more or fewer than seven shots of reticle 900. Shot map 904 includes a first shot map region 904a and a second shot map region 904b (shown shaded for ease of viewing). In first shot map region 904a, each shot of reticle 900 has a first orientation (e.g., as in FIG. 9A). In second shot map region 904b, each shot of reticle 900 has a second orientation (e.g., rotated 180° relative to first orientation). Shot map 904 includes twenty-eight die 902, including four partial die 902a, 902b, 902c and 902d. In an embodiment, a portion of first die region 908 is cut off in each of partial die 902a, 902b, 902c and 902d. In an embodiment, no portion of second die region 910 is cut off in any of partial die 902a, 902b, 902c and 902d.

FIG. 9C depicts multiple die 912 printed using reticle 900 of FIG. 9A on a wafer 914. Each die 912 includes first die region 908 and second die region 910. Wafer 914 also includes first partial memory die 916a, 916b, 916c and 916d.

First partial memory die 916a, 916b, 916c and 916d each include a partial first die region 908′ and a second die region 910, and are each missing portions of first die region 908 that were not printed (or otherwise fabricated) on wafer 914. In an embodiment, first partial memory die 916a, 916b, 916c and 916d each can be successfully used as a partially operable memory die. Wafer 914 includes no second partial memory die that include partial second die region 910. Thus, compared with wafer 604 of FIG. 6, wafer 914 includes two additional first partial memory die that can be successfully used as a partially operable memory die, and includes no second partial memory die that cannot be successfully used as a partially operable memory die.

Although the description above described die 702, 802 and 902 as memory die, persons of ordinary skill in the art will understand that die 702, 802 and 902 alternatively may be other types of integrated circuits that have a first die region 708, 808 and 908, respectively, that includes multiple arrays of circuits and/or duplicate circuits, such as FPGAs, CPUs, GPUs, ASICs, or other similar integrated circuit. For example, a partial die 4-core CPU may be used as a 3-core CPU, a partial die dual-core CPU may be used as a single-core CPU, and so on.

Thus, as described above, an apparatus is provided that includes a reticle including a die, the reticle configured to increase a number of partial die that can be successfully used as partially operable die.

One embodiment includes an apparatus is provided that includes a reticle including a die, the reticle configured to reduce a number of partial die that cannot be successfully used as partially operable die.

One embodiment includes a method including forming a reticle that includes a die having a first die region and a second die region, and forming a shot map that includes an arrangement of shots of the reticle on a wafer. The shot map includes a partial die. A portion of the first die region is cut off in the partial die and no portion of the second die region is cut off in the partial die.

For purposes of this document, each process associated with the disclosed technology may be performed continuously and by one or more computing devices. Each step in a process may be performed by the same or different computing devices as those used in other steps, and each step need not necessarily be performed by a single computing device.

For purposes of this document, reference in the specification to “an embodiment,” “one embodiment,” “some embodiments,” or “another embodiment” may be used to described different embodiments and do not necessarily refer to the same embodiment.

For purposes of this document, a connection can be a direct connection or an indirect connection (e.g., via another part).

For purposes of this document, the term “set” of objects may refer to a “set” of one or more of the objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. An apparatus comprising:
a reticle comprising a die, the reticle configured to increase a number of partial die that can be successfully used as partially operable die.

2. The apparatus of claim 1, wherein the reticle comprises a plurality of die.

3. The apparatus of claim 1, wherein the reticle comprises a first reticle portion and a second reticle portion.

4. The apparatus of claim 3, wherein the second reticle portion comprises a vertically mirrored image of the first reticle portion.

5. The apparatus of claim 3, wherein the second reticle portion comprises a vertically and horizontally mirrored image of the first reticle portion.

6. The apparatus of claim 3, wherein the second reticle portion comprises a same image of the first reticle portion.

7. The apparatus of claim 1, wherein the die comprises a memory die.

8. The apparatus of claim 1, wherein the die comprises a first die region and a second die region.

9. The apparatus of claim 8, wherein the first die region comprises portions of a substrate, and memory blocks that include memory cells, NAND strings, bit lines, word lines, select lines and dielectric regions.

10. The apparatus of claim 8, wherein the second die region comprises support circuits connected to circuits in the first die region.

11. An apparatus comprising:
a reticle comprising a die, the reticle configured to reduce a number of partial die that cannot be successfully used as partially operable die.

12. The apparatus of claim 11, wherein the reticle comprises a plurality of memory die.

13. The apparatus of claim 11, wherein the reticle comprises a first reticle portion and a second reticle portion that comprises a vertically mirrored image of the first reticle portion.

14. The apparatus of claim 11, wherein the reticle comprises a first reticle portion and a second reticle portion that comprises a vertically and horizontally mirrored image of the first reticle portion.

15. The apparatus of claim 11, wherein the reticle comprises a first reticle portion and a second reticle portion that comprises a same image of the first reticle portion.

16. The apparatus of claim 11, wherein the die comprises a first die region comprising portions of a substrate, and memory blocks that include memory cells, NAND strings, bit lines, word lines, select lines and dielectric regions.

17. The apparatus of claim 11, wherein the die comprises a second die region comprising support circuits connected to circuits in the first die region.

18. A method comprising:
forming a reticle comprising a die comprising a first die region and a second die region; and
forming a shot map comprising an arrangement of shots of the reticle on a wafer, the shot map comprising a partial die, wherein a portion of the first die region is cut off in the partial die and no portion of the second die region is cut off in the partial die.

19. The method of claim 18, wherein the first die region comprises portions of a substrate, and memory blocks that include memory cells, NAND strings, bit lines, word lines, select lines and dielectric regions.

20. The method of claim 18, wherein the second die region comprises support circuits connected to circuits in the first die region.
